(19) United States
(12) Patent Application Publication
(10) Pub. No.: US 2020/0326950 A1
(43) Pub. Date: Oct. 15, 2020

(54) SIMULATION APPARATUS, SIMULATION METHOD, AND INFORMATION PROCESSING APPARATUS

(71) Applicant: Oki Data Corporation, Tokyo (JP)

(72) Inventor: Satoshi HANZAWA, Tokyo (JP)

(73) Assignee: Oki Data Corporation, Tokyo (JP)

(21) Appl. No.: 16/837,963

(22) Filed: Apr. 1, 2020

(30) Foreign Application Priority Data
Apr. 10, 2019 (JP) 2019-075130

(51) Int. Cl. G06F 9/38; G06F 9/30; G06F 30/20; G06F 3/06

(52) U.S. Cl. CPC G06F 9/3842; G06F 9/30043; G06F 30/20; G06F 3/0679; G06F 3/0607; G06F 3/0658; G06F 3/0659

(57) ABSTRACT

A simulation apparatus according to one or more embodiments may include: a CPU model that mimics a central processing unit (CPU) which reads and executes command codes; a model production unit that produces a storage unit model which mimics a storage unit which stores a control program including the command codes; an undefined code writing unit that writes an undefined code which is not defined in the CPU, into at least a portion of a storage area of the storage unit model; a control program writing unit that writes the control program specified by a user, into the storage area of the storage unit model in which the undefined code has been written; and a command code execution unit that sequentially reads the command codes from the storage unit model and causes the CPU model to sequentially execute the command codes.

### CROSS REFERENCE TO RELATED APPLICATIONS

This application claims priority based on 35 USC 119 from prior Japanese Patent Application No. 2019-075130 filed on Apr. 10, 2019, entitled “SIMULATION APPARATUS, SIMULATION METHOD, AND INFORMATION PROCESSING APPARATUS”, the entire contents of which are incorporated herein by reference.

### BACKGROUND

The disclosure may relate to simulation apparatuses, simulation methods, and information processing apparatuses, and is preferably applicable to, for example, a simulation apparatus that simulates a printer.

In a related art, simulation apparatuses that are widely used are those that simulate the operation of hardware performed when the hardware executes software, and thereby verify, analyze, etc., the operation of the software.

In such simulation apparatuses, for example, in the case where a printer is simulated, models of the parts of the printer, e.g., a conveyance unit that conveys paper, an image formation unit that forms an image, a fixation unit that fixes an image on paper, and a control unit that controls these units, are produced.

Of these models, the control unit model produced by modeling the control unit includes models of a central processing unit (CPU) that reads and executes a command code, a read only memory (ROM) that stores various kinds of information such as a control program, a random access memory (RAM) that temporarily stores information, etc., which are simulated on software.

Under the above settings, in the simulation apparatus, in the model of the control unit, firmware (i.e., a program) including command codes is stored into the model of the ROM, and the model of the CPU reads, decodes, and executes (command process) the command codes of the firmware in sequence (see, for example, Patent Document 1: Japanese Patent Application Publication No. JP11-250115 (FIG. 1, etc.)). As a result, the simulation apparatus can easily verify, on software, whether or not the firmware is normally operated on the printer.

Patent Document 1: Japanese Patent Application Publication No. JP11-250115

### SUMMARY

Incidentally, in some simulation apparatuses, during development or correction of firmware, several pieces of firmware are prepared as a file, and a simulation process is performed for each piece of firmware, while one piece of firmware loaded is replaced with another as appropriate. In some of these simulation apparatuses, for example, a firmware file is specified by the user's operation using a file name or the like, the firmware associated with the file name is written into the model of the ROM, and thereafter, a simulation process is started, whereby the efficiency of work is improved.

However, for example, in the case where the user frequently updates firmware and also changes the file name as appropriate, the user may incorrectly specify the file, specifically incorrectly specify the file name itself, the file path, etc. In such a case, in the simulation apparatus, a simulation process is started without firmware loaded after initialization of the model of the ROM, e.g., with “00H” written into each address.

In most cases, the command code “00H” is assign “NOP,” which means that no process is performed. Therefore, in the simulation apparatus, the model of the control unit sequentially reads “00H” from each address in the model of the ROM while allowing a program counter to be sequentially updated, without performing any process, i.e., without causing the printer to perform any operation. In such a case, the printer fails to be operated on software, and therefore, the user, operating the simulation apparatus, may estimate that there is a problem with, for example, firmware, and may perform useless work such as trying to find the cause for the problem.

Thus, there has been the problem with simulation apparatuses that when a simulation process is performed without a program such as firmware normally written in the ROM model, and a normal operation result is not obtained, it is difficult for the user to find the cause.

An object of an aspect of one or more embodiments is to propose a simulation apparatus, simulation method, and information processing apparatus that can quickly detect an abnormality attributed to writing of a program.

An aspect of one or more embodiments may be a simulation apparatus that may include: a CPU model that mimics a central processing unit (CPU) which reads and executes command codes; a model production unit that produces a storage unit model which mimics a storage unit which stores a control program including the command codes; an undefined code writing unit that writes an undefined code which is not defined in the CPU, into at least a portion of a storage area of the storage unit model; a control program writing unit that writes the control program specified by a user, into the storage area of the storage unit model in which the undefined code has been written; and a command code execution unit that sequentially reads the command codes from the storage unit model and causes the CPU model to sequentially execute the command codes.

An aspect of one or more embodiments may be a simulation method that may include: forming a CPU model that mimics a CPU which reads and executes command codes, and a storage unit model which mimics a storage unit which stores a control program including the command codes, using a model production unit; writing an undefined code which is not defined in the CPU, into at least a portion of a storage area of the storage unit model, using an undefined code writing unit; writing the control program specified by a user, into the storage area of the storage unit model in which the undefined code has been written, using a control program writing unit; and sequentially reading the command codes from the storage unit model and causing the CPU model to sequentially execute the command codes, using a command code execution unit.

An aspect of one or more embodiments may be an information processing apparatus that may include: a CPU that reads and executes command codes; a storage unit that stores a control program including the command codes; an undefined code writing unit that writes an undefined code which is not defined in the CPU, into at least a portion of a storage area of the storage unit; a control program writing unit that writes the control program into the storage area of the storage unit model in which the undefined code has been written; and an abnormality processing unit that when the CPU reads and executes the command code of the control program from the storage unit wherein the command code is the undefined code, performs at least one of a stopping process of stopping the execution of the control program and a notification process of notifying that the undefined code has been read.

According to at least one of the above aspects, the undefined code is previously written into the storage unit or the storage unit model before the control program is written into the storage unit or the storage unit model. The CPU or the CPU model performs a process by fetching and decoding the command codes of the control program from the storage unit or the storage unit model. Therefore, when the command code fetched and decoded from the storage unit or the storage unit model is the undefined code, it is determined that the control program has not been normally written into the storage unit or the storage unit model. Thus, such an abnormality can be quickly detected.

According to at least one of the above aspects, a simulation apparatus, simulation method, and information processing apparatus that can quickly detect an abnormality attributed to writing of a program can be provided.

### BRIEF DESCRIPTION OF DRAWINGS

FIG. 1 is a schematic block diagram illustrating a view of a configuration of a simulation apparatus according to a first embodiment.

FIG. 2 is a schematic block diagram illustrating a view of a configuration of a printer model.

FIG. 3 is a schematic diagram illustrating a view of a configuration of a model display window.

FIG. 4 is a flowchart illustrating a simulation process according to a first embodiment.

FIG. 5 is a schematic diagram illustrating dump data of a ROM model in its initial state.

FIG. 6 is a schematic diagram illustrating dump data of a ROM model in which an undefined code has been written.

FIG. 7 is a schematic diagram illustrating dump data of a ROM model in which firmware has been loaded.

FIG. 8 is a flowchart illustrating a resetting process according to a first embodiment.

FIG. 9 is a flowchart illustrating a firmware execution process according to a first embodiment.

FIG. 10 is a schematic diagram illustrating a view of a displayed abnormality notification window.

FIG. 11 is a schematic block diagram illustrating a view of a configuration of a simulation apparatus according to a comparative example.

FIG. 12 is a flowchart illustrating a simulation process according to a comparative example.

FIG. 13 is a flowchart illustrating a firmware execution process according to a comparative example.

FIG. 14 is a schematic block diagram illustrating a configuration of a printer according to a second embodiment.

FIGS. 15A to 15C are schematic diagrams illustrating a memory map of an external memory and dump data according to a second embodiment.

FIG. 16 is a schematic diagram illustrating triggering causes for exceptional processes and storage addresses.

FIG. 17 is a flowchart illustrating a firmware updating process according to a second embodiment.

FIG. 18 is a flowchart illustrating a resetting process according to a second embodiment.

FIG. 19 is a flowchart illustrating a firmware execution process according to a second embodiment.

FIG. 20 is a flowchart illustrating an undefined code execution exceptional process.

FIG. 21 is a schematic block diagram illustrating a view of a configuration of a printer according to a third embodiment.

FIGS. 22A to 22C are schematic diagrams illustrating a memory map of an internal RAM and dump data according to a third embodiment.

FIG. 23 is a flowchart illustrating a firmware transfer process according to a third embodiment.

FIG. 24 is a flowchart illustrating an error notification process according to a third embodiment.

FIG. 25 is a schematic diagram illustrating a timing chart of an error notification process.

### DETAILED DESCRIPTION

Descriptions are provided hereinbelow for one or more embodiments based on the drawings. In the respective drawings referenced herein, the same constituents are designated by the same reference numerals and duplicate explanation concerning the same constituents is omitted. All of the drawings are provided to illustrate the respective examples only.

### 1. First Embodiment

### [1-1. Configuration of Simulation Apparatus]

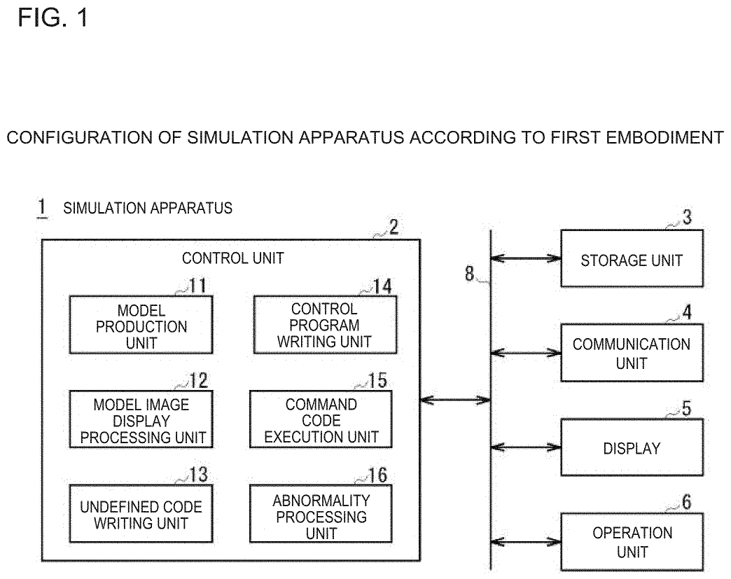

As indicated by a schematic block diagram illustrated in FIG. 1, in a simulation apparatus 1 according to a first embodiment, a control unit 2, a storage unit 3, a communication unit 4, a display 5, and an operation unit 6 are coupled together through a bus 8. The simulation apparatus 1 produces a printer model that mimics a printer (also referred to as an “image formation apparatus”) on software, and performs a simulation process of executing firmware on the printer model. Incidentally, the firmware is a program for controlling pieces of hardware constituting the printer so that a printing process, etc., are performed. The firmware is also called a “control program.”

The control unit 2 has a central processing unit (CPU), a read only memory (ROM), a random access memory (RAM), etc., which are not illustrated. The control nit 2 reads various programs such as firmware from the ROM and the storage unit 3, and executes the programs to form functional blocks thereinside, and performs various processes (described in detail below).

The storage unit 3, which is, for example, a non-volatile storage medium, such as a hard disk drive or flash memory, stores various kinds of information. The storage unit 3 stores files or the like of a simulation program, firmware, etc., described below. The communication unit 4 is, for example, an interface supporting a wired local area network (LAN) compliant with a standard such as the Institute of Electrical and Electronics Engineers (IEEE) 802.3u/ab or a wireless LAN compliant with IEEE 802.11a/b/g/n/ac or the like. The communication unit 4, which is coupled to a predetermined network (not illustrated), exchanges information with an external information processing apparatus (not illustrated).

The display 5, which is, for example, a liquid crystal display, displays and presents various kinds of information using characters, graphics, etc., to the user. The operation unit 6, which is, for example, a keyboard, mouse, or touchpad, receives the user's various input operations.

The control unit 2 reads and executes a simulation program from the storage unit 3 to produce therein functional blocks such as a model production unit 11, a model image display processing unit 12, an undefined code writing unit 13, a control program writing unit 14, a command code execution unit 15, and an abnormality processing unit 16.

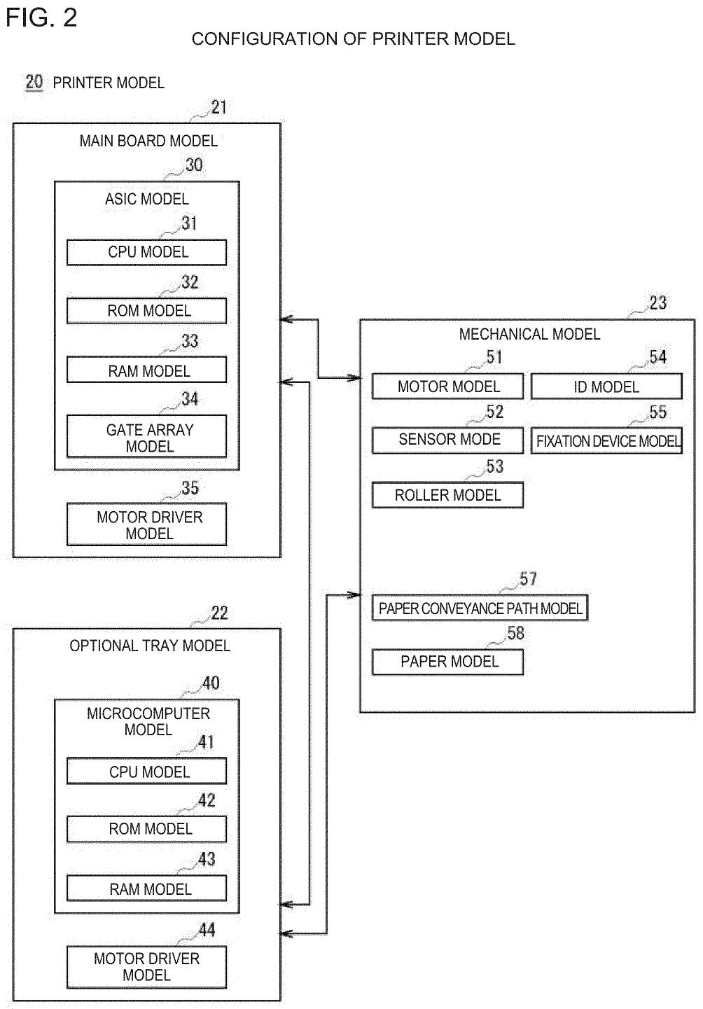

As illustrated in FIG. 2, the model production unit 11 produces a printer model 20 that mimics parts constituting a printer. Specifically, the printer model 20 roughly includes a main board model 21, an optional tray model 22, and a mechanical model 23.

The main board model 21, which is a model of a main board that controls parts of the printer, mainly includes an ASIC model 30 that is a model of an application specific integrated circuit (ASIC). In the ASIC model 30, provided are a CPU model 31, ROM model 32, RAM model 33, and gate array model 34 that are models of a CPU, ROM, RAM, and gate array, respectively.

The CPU model 31, which includes models of a computation unit, various registers, a program counter, etc. (none of them is illustrated), can simulate, on software, operations (behaviors) similar to operations of an actual CPU, such as fetching (obtaining), decoding, and execution (command execution) of a command code. The ROM model 32 and the RAM model 33 have a storage area similar to that of an actual ROM and RAM, and are assigned addresses, and operate in a manner similar to that of an actual ROM and RAM to store data in association with the addresses and allow reading of the data.

In the CPU model 31, like an actual CPU, 2-byte command codes are previously defined. The CPU model 31 regards data read and obtained from the ROM model 32 or the like as a command code, and executes a process corresponding to the command code. Note that in the CPU model 31, only a portion of 256 possible values represented by 2-byte data are defined as a command code, and the remainder is undefined. The CPU model 31 is configured to perform an exceptional process such as jumping to a predetermined address like an actual CPU when obtaining an undefined command code (hereinafter referred to as an “undefined code”).

The gate array model 34 is allowed to execute, on software, an operation (behavior) similar to that of a gate array formed in an actual ASIC. In addition, the main board model 21 is provided with a motor driver model 35 that is a model of a motor driver for controlling a motor that generates and supplies drive force to each part.

The optional tray model 22 is a model of a paper tray that is an option attachable to the printer and an optional tray that is a peripheral part for the paper tray. The optional tray model 22 mainly includes a microcomputer model 40 that is a model of a microcomputer that controls each part. The microcomputer model 40 is provided with a CPU model 41, a ROM model 42, and a RAM model 43 like the ASIC model 30. The optional tray model 22 is also provided with a motor driver model 44 that is a model of a motor driver like the main board model 21.

The mechanical model 23 is provided with a model of each part provided in the printer. Specifically, the mechanical model 23 is provided with a motor model 51 that is a model of a motor which generates drive force, a sensor model 52 that is a model of a sensor which detects the presence or absence of paper, etc., and a roller model 53 that is a model of a cylindrical roller which is rotated to convey paper, for example.

The mechanical model 23 is also provided with an image drum (ID) model 54 that is a model of an image drum (ID) which forms a toner image using a toner, and a fixation device model 55 that is a model of a fixation device which applies heat and pressure to paper having a toner image transferred thereon for fixation. The mechanical model 23 is also provided with a paper conveyance path model 57 that is a model of a paper conveyance path on which paper is conveyed, and a paper model 58 that is a model of paper.

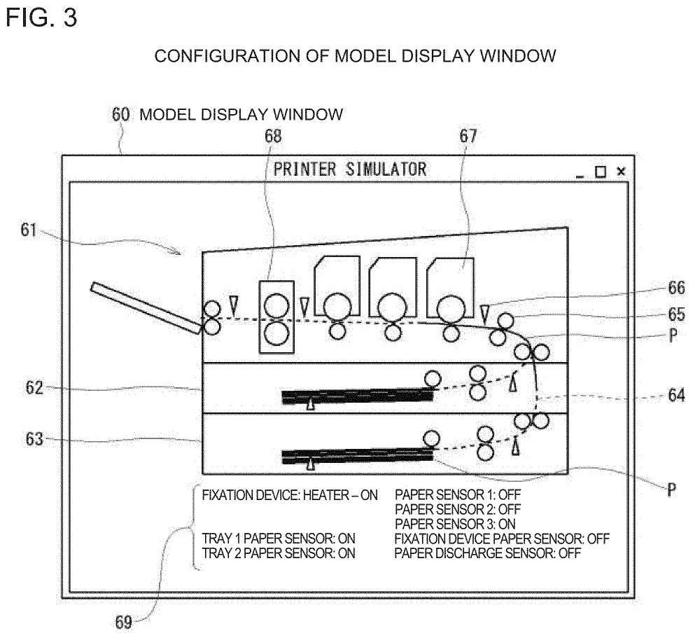

The model image display processing unit 12 of the control unit 2 (FIG. 1) causes the display 5 to display a model display window 60 that presents an image representing a condition, operation, etc., of the printer, as illustrated in FIG. 3, based on an operation or condition of each part of the printer model 20 (FIG. 2) produced by the model production unit 11.

The model display window 60 is provided with a printer body section 61 that schematically represents the body of the printer. The printer body section 61 is provided with a paper tray 62 that stores paper P, and an optional tray 63 that is optionally attached, as an additional paper tray, to the printer body section 61. The printer body section 61 is also provided with a paper conveyance path 64 on which paper P is conveyed, a roller 65 that transmits drive force to paper P, a paper sensor 66 that detects paper P, an image drum 67 that forms a toner image, and a fixation device 68 that applies heat and pressure to paper P having a toner image transferred thereon.

During the simulation process performed in the simulation apparatus 1, the model display window 60 changes, as appropriate, images of the printer body section 61, the paper tray 62, and the optional tray 63, depending on operations of these parts. For example, the model display window 60 sequentially changes the position of paper P along the conveyance path. In addition, a condition display section 69 that displays a condition of each part using characters is provided in the model display window 60 below the printer body section 61. The condition display section 69 displays, for example, an operation condition of the fixation device, the result of detection of paper P by each sensor, etc., using characters.

Thus, the model display window 60 can present how each part of the printer is operated in the simulation process, to the user, using an image or characters.

The undefined code writing unit 13 of the control unit 2 (FIG. 1) writes an undefined code described below into the ROM model 32 (FIG. 2) produced by the model production unit 11 (described in detail below). The control program writing unit 14 (FIG. 1) reads a control program stored in the storage unit 3, i.e., firmware for operating the printer, and writes the control program into the ROM model 32 (FIG. 2). The command code execution unit 15 (FIG. 1) causes the CPU model 31 (FIG. 2) to execute a command code, specifically processes such as fetching (reading), decoding, and executing (command execution) of a command code from the ROM model 32. The abnormality processing unit 16, when an abnormality is detected, performs a predetermined abnormality addressing process (described in detail below).

Thus, in the simulation process, the simulation apparatus 1 produces a model of each part included in a printer on software, sequentially reads each command code of firmware stored in the ROM model 32 and executes the command code using the CPU model 31, to simulate an operation of the printer.

### [1-2. Simulation Process]

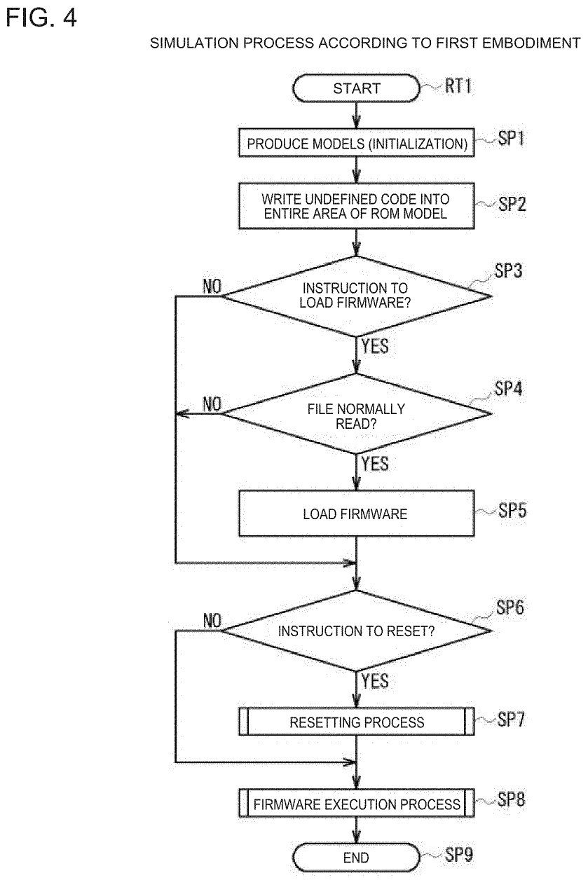

Next, execution of the simulation process in the simulation apparatus 1 is described. The control unit 2 of the simulation apparatus 1, when receiving, as an instruction to start the simulation process from the user, for example, a file name representing an executable file of a simulation program on a command line, reads and executes the simulation program from the storage unit 3. As a result, the control unit 2 produces each functional block of FIG. 1 therein, and thereafter, starts a simulation process RT1 illustrated in FIG. 4, and transitions to the first step SP1.

In step SP1, the control unit 2 produces the printer model 20 (FIG. 2) using the model production unit 11 (FIG. 1), and causes the model image display processing unit 12 (FIG. 1) to display the model display window 60 (FIG. 3) on the display 5 (FIG. 1), and proceeds to the next step SP2.

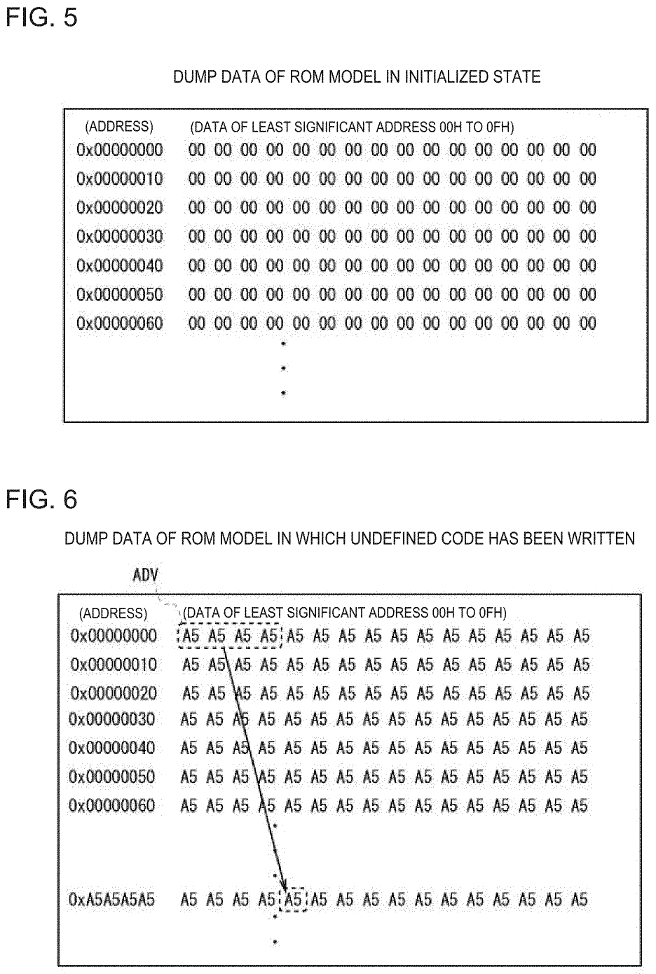

At this time, each part of the printer model 20 has just been newly produced, i.e., is in its initial state. For example, all registers (not illustrated), etc., of the CPU model 31 in the main board model 21 are in their initialized states. In addition, the ROM model 32 has the value “00H” at all addresses thereof, as indicated by dump data illustrated in FIG. 5. The value “00H” is defined as “NOP,” which means that no execution is performed for a command code of the CPU model 31.

In step SP2, the control unit 2 writes “A5H,” which is an undefined code, into the entire area of the ROM model 32 in the printer model 20 (FIG. 2), using the undefined code writing unit 13 (FIG. 1), and proceeds to the next step SP3. As a result, the ROM model 32 has the undefined code “A5H” written at all addresses thereof, as indicated by dump data illustrated in FIG. 6.

In step SP3, the control unit 2 determines whether or not an instruction to load firmware, i.e., an instruction to read firmware stored as a file in the storage unit 3 (FIG. 1) and write the firmware into the ROM model 32, has been received from the user. In this case, for example, when a file name representing an executable file of a simulation program is input on a command line, then when the file name of firmware is specified as an argument, the control unit 2 determines that the control unit 2 has received an instruction to load the firmware. Here, when the result of the determination is positive, the control unit 2 proceeds to the next step SP4.

In step SP4, the control unit 2 determines whether or not the file of the firmware has been normally read from the storage unit 3. Here, when the result of the determination is positive, the control unit 2 proceeds to the next step SP5.

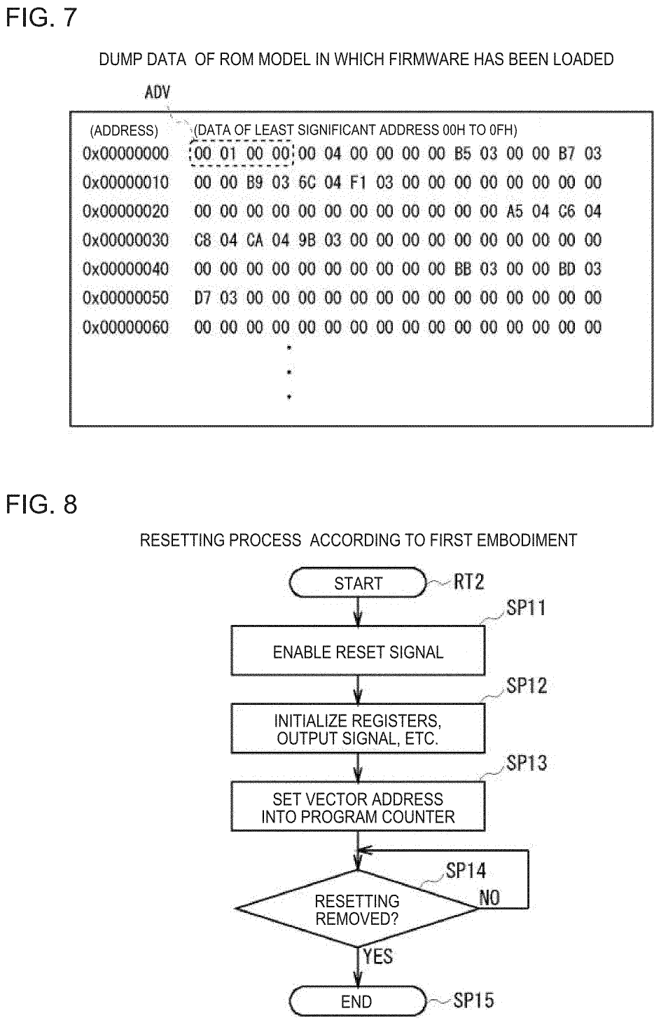

In step SP5, the control unit 2 performs a process of sequentially writing, i.e., loading, the file of the firmware (control program) read from the storage unit 3 into the ROM model 32, using the control program writing unit 14 (FIG. 1), and proceeds to the next step SP6. As a result, the ROM model 32 has command codes constituting the firmware sequentially written from the start address, as indicated by dump data illustrated in FIG. 7. In other words, at this time, undefined codes are overwritten by the command codes of the firmware. Incidentally, in the case where the size of the firmware is smaller than the storage capacity of the ROM model 32, some undefined codes are left near the highest address or the like after the writing of the firmware is finished.

Incidentally, in the printer model 20, 4 bytes from address 0x00000000 illustrated in FIG. 6 represents a vector address ADV that is an address to which a jump should be made immediately after a resetting process. In FIG. 6, as an example, the vector address ADV at the time of resetting is the address “10000H.” Specifically, when a resetting process is performed, the CPU model 31 regards 4-byte data from address 0x00000000 as the vector address ADV, and reads and sets the 4-byte data into the program counter, and thereby jumps to the vector address and continues to execute the process.

Meanwhile, when the result of the determination in step SP3 is negative, this means that firmware does not need to be loaded. At this time, the control unit 2 proceeds to the next step SP6. When the result of the determination in step SP4 is negative, i.e., an instruction to load firmware has been received from the user, and the firmware has failed to be normally read, the control unit 2 also proceeds to step SP6. This corresponds to, for example, the case where the file name or path name of firmware specified by the user is incorrect. In that case, the ROM model 32 remains in the state that undefined codes are written in step SP2 (FIG. 6).

In step SP6, the control unit 2 determines whether or not the control unit 2 has received an instruction to perform resetting. At this time, for example, when a command line from the user contains a predetermined argument, the control unit 2 receives the command as an instruction to perform resetting. When the control unit 2 has received an instruction to load firmware in step SP3 or the like, the control unit 2 also determines that the control unit 2 has received an instruction to perform resetting. Here, when the result of the determination is positive, the control unit 2 proceeds to the next step SP7.

In step SP7, the control unit 2 executes a resetting process as a subroutine. Specifically, the control unit 2 reads and executes a reset program from the storage unit 3 (FIG. 1) to start a resetting process RT2 illustrated in FIG. 8, and proceeds to step SP11.

In step SP11, the control unit 2 enables a reset signal, and proceeds to the next step SP12. Here, the reset signal is enabled during a series of processes (hereinafter referred to as a “resetting process”) for operating a printer from the initial state, including initialization of various values, and is disabled at the end of the resetting process.

In step SP12, the control unit 2 initializes each register (not illustrated) in the CPU model 31, an output signal, etc., and proceeds to the next step SP13. In step SP13, the control unit 2 sets a predetermined vector address (e.g. 00000000H) as a program start address into the program counter, and proceeds to the next step SP14.

In step SP14, the control unit 2 determines whether or not resetting is removed, specifically whether or not the reset signal is disabled. Here, when the result of the determination is negative, the control unit 2 repeats step SP14, and waits until the reset signal is disabled.

Meanwhile, when the result of the determination in step SP14 is positive, the control unit 2 proceeds to the next step SP15, in which the control unit 2 ends the resetting process RT2, returns to step SP7 in the simulation process RT1 (FIG. 4), and proceeds to the next step SP8. When the result of the determination in step SP6 is negative, control unit 2 proceeds to the next step SP8 without performing an initialization process.

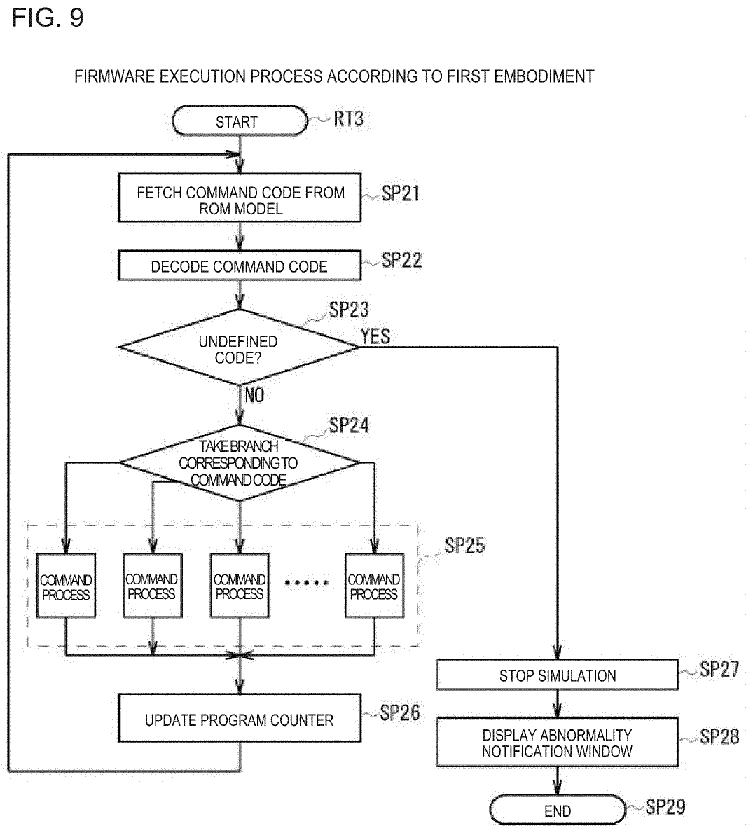

In step SP8, the control unit 2 executes a firmware execution process as a subroutine. Specifically, the control unit 2 reads and executes a firmware execution program from the storage unit 3 (FIG. 1) to start a firmware execution process RT3 illustrated in FIG. 9, and proceeds to step SP21.

In step SP21, the control unit 2 fetches (i.e., obtains) a command code from an address indicated by the program counter (not illustrated) in the ROM model 32, using the command code execution unit 15 (FIG. 1), and proceeds to the next step SP22. In step SP22, the control unit 2 decodes the fetched command code using the command code execution unit 15 (FIG. 1), and proceeds to the next step SP23.

In step SP23, the control unit 2 determines whether or not the command code is an undefined code, using the command code execution unit 15 (FIG. 1). Here, when the result of the determination is negative, this means that the command code is not an undefined code, and is one of the previously defined command codes. This also means that at the current address in the ROM model 32, firmware has been normally written in step SP5 after an undefined code was written in step SP2 (FIG. 4). At this time, the control unit 2 proceeds to the next step SP24.

In step SP24, the control unit 2 takes a branch for a process corresponding to the command code using the command code execution unit 15 (FIG. 1). In the following step SP25, the control unit 2 executes a command process corresponding to the command code, and proceeds to the next step SP26. In step SP26, the control unit 2 updates the program counter, and returns to step SP21 again. As a result, the control unit 2 repeats the above series of processes for the next address.

Meanwhile, when the result of the determination in step SP23 is positive, this means that the command code is an undefined code, and therefore, firmware has not been normally written in step SP5 after an undefined code was written at the current address in the ROM model 32 in step SP2 (FIG. 4). This also means that at least a portion of firmware is not normally written in the ROM model 32, and therefore, the operation of the firmware cannot be correctly verified in the simulation apparatus 1, being in the current state. At this time, the control unit 2 proceeds to the next step SP27.

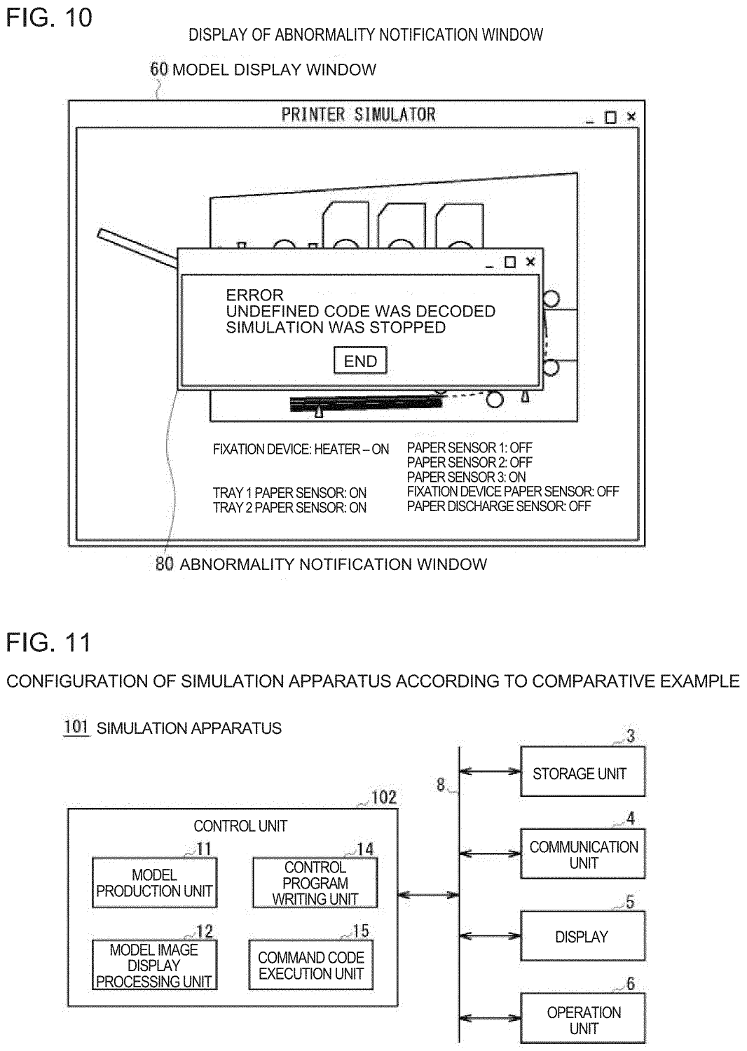

In step SP27, the control unit 2 stops the simulation using the abnormality processing unit 16 (FIG. 2), and proceeds to the next step SP28. In step SP28, as illustrated in FIG. 10, the control unit 2 causes the display 5 (FIG. 1), using the abnormality processing unit 16 (FIG. 2), to display an abnormality notification window 80, which overlays the model display window 60 (i.e., the abnormality notification window 80 is closer to the user than is the model display window 60), and proceeds to the next step SP29.

The abnormality notification window 80 displays messages, e.g., “ERROR,” “Undefined command code was decoded,” and “Simulation was stopped.” Therefore, the user, viewing the abnormality notification window 80, can immediately understand that an undefined command code was decoded, and therefore, the simulation process has been stopped.

In step SP29, the control unit 2 ends the firmware execution process RT3, returns to step SP8 in the simulation process RT1 (FIG. 4), and proceeds to the next step SP9, in which the control unit 2 ends the simulation process RT1.

### [1-3. Effects, Etc.]

With the above configuration, in the simulation apparatus 1 according to a first embodiment, an undefined code is written into the entire area of the ROM model 32 immediately after the start of the simulation process (FIGS. 4 and 6).

Here, in order to compare with the simulation apparatus 1, a simulation apparatus 101 according to a comparative example is described. As illustrated in FIG. 11 corresponding to FIG. 1, the simulation apparatus 101 according to a comparative example is different from the simulation apparatus 1 according to this embodiment in that the former has a control unit 102 instead of the control unit 2. The control unit 102 is similar to the control unit 2 (FIG. 1), except that the undefined code writing unit 13 and the abnormality processing unit 16 are removed.

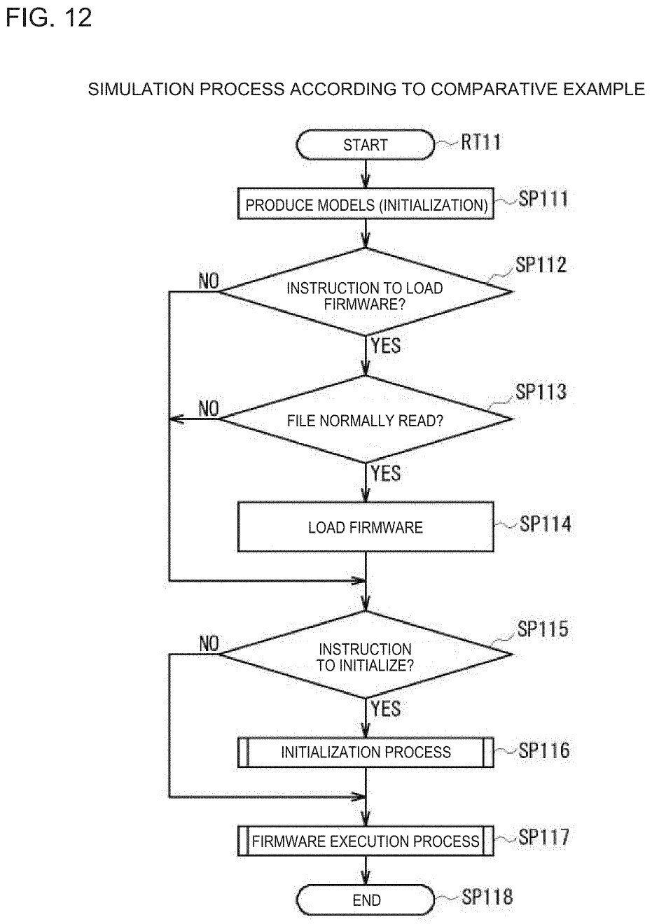

When the control unit 102 of the simulation apparatus 101 according to a comparative example executes the simulation process, the control unit 102 executes a simulation process RT11 (FIG. 12) according to a comparative example instead of the simulation process RT1 (FIG. 4) according to this embodiment.

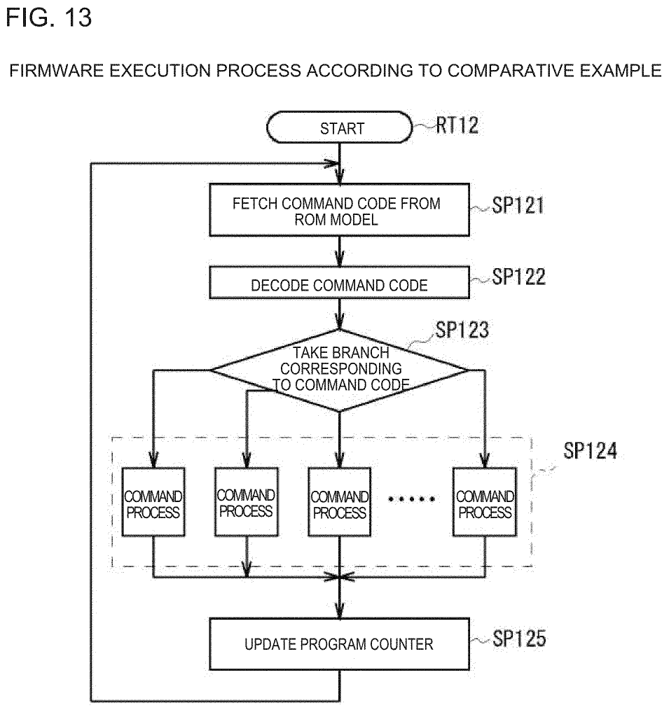

The simulation process RT11 according to a comparative example is partially similar to, and different from the simulation process RT1 (FIG. 4) in that the process corresponding to step SP2 is removed, and in step SP117, a conventional firmware execution process RT12 illustrated in FIG. 13 is executed as a subroutine. The firmware execution process RT12 (FIG. 13) according to a comparative example is partially similar to, and different from the firmware execution process RT3 (FIG. 9) in that the processes corresponding to steps SP23, SP27, SP28, and SP29 are removed.

Therefore, in the simulation apparatus 101 according to a comparative example, when the file name specified by the user is incorrect, the result of determination in step SP113 of the simulation process RT11 (FIG. 12) according to a comparative example is negative, and therefore, step SP115 and following steps are executed. As a result, in the simulation apparatus 101 according to a comparative example, a firmware execution process is performed in step SP117 with the ROM model 32 remaining in the state initialized in step SP111 (FIG. 5), i.e., “00H” stored in the entire area.

In that case, the simulation apparatus 101 according to a comparative example repeats, in the firmware execution process RT12 (FIG. 13) according to a comparative example, a series of processes including sequentially reading the command code “00H” from each address of the ROM model 32, and performing no process. Therefore, the simulation apparatus 101 according to a comparative example does not perform any operation in the printer model 20 (FIG. 2), and continues to display the model display window 60 (FIG. 3) without a change. In that case, the user, operating the simulation apparatus 101 according to a comparative example, can recognize that the printer model 20 is not normally operating, but cannot immediately understand the cause, and therefore, needs to do work for finding the cause.

In contrast to this, in the simulation apparatus 1 according to this embodiment, an undefined code is written into the entire area of the ROM model 32 (FIG. 6) in step SP2 of the simulation process RT1 (FIG. 4). Therefore, in the simulation apparatus 1, even when the file name specified by the user is incorrect, the result of the determination in step SP4 of the simulation process RT1 (FIG. 4) is negative, step SP6 and following steps are executed. Therefore, the simulation apparatus 1 executes the firmware execution process in step SP8 with the undefined codes written in step SP2 (FIG. 6) left in the ROM model 32, i.e., “A5H” stored in the entire area.

In this case, the address stored at the vector address ADV of the ROM model 32 is “A5A5A5A5H,” the control unit 2 of the simulation apparatus 1 sets that address into the program counter in the firmware execution process RT3 (FIG. 9). Next, the control unit 2 reads the undefined code “A5H” from the address “A5A5A5A5H,” and therefore, the result of the determination in step SP23 is positive. Therefore, in steps SP27 and SP28, the control unit 2 stops simulation and causes the display 5 to display the abnormality notification window 80 (FIG. 10).

As a result, the user, having been operating the simulation apparatus 1, can immediately recognize that an undefined code has been decoded, and based on this, can easily understand that loading of firmware is highly likely to be unsuccessful, i.e., the specified file name is highly likely to be incorrect, and therefore, can immediately address the trouble, e.g., corrects the file name. In other words, at this time, the user can understand that an undefined code (i.e., a bug) is less likely to be contained in the firmware. Therefore, by giving a low priority to work that it takes time and effort to do such as checking of the details of the firmware, the cause for the trouble can be quickly removed.

In addition, in the simulation apparatus 1, at the stage that an undefined code is fetched and decoded from the ROM model 32, simulation can be stopped and the abnormality notification window 80 (FIG. 10) can be displayed (FIG. 9). Therefore, in the simulation apparatus 1, it is not necessary to meticulously set conditions for each register, etc., in order to stop the simulation process, and it is not necessary for the user to do extra work.

Furthermore, in the simulation apparatus 1, simulation is stopped and the abnormality notification window 80 (FIG. 10) is displayed base on whether or not a command code fetched and decoded from the ROM model 32 is an undefined code. Therefore, in the simulation apparatus 1, the printer model 20 does not need to include a mechanism for detecting an undefined code, and highly-accurate verification can be performed by causing the printer model 20, the CPU model 31, etc., to perform operations similar to those of an actual printer, CPU, etc.

In addition to this, in the simulation apparatus 1, in step SP2 of the simulation process RT1 (FIG. 4), an undefined code is written into the entire area of the ROM model 32. Therefore, in the simulation apparatus 1, even when a file of firmware stored in the storage unit 3 is damaged in the middle of the file, so that only a portion of the file has been normally loaded, the failure to normally write the firmware can be detected at the time that an undefined code is fetched and decoded.

With the above configuration, in the simulation apparatus 1 according to a first embodiment, in the simulation process, an undefined code is previously written into the entire area of the ROM model 32, before firmware is loaded into the ROM model 32. When the file name specified by the user is incorrect, the simulation apparatus 1 performs a firmware execution process with undefined codes written in the ROM model 32 left, and therefore, when fetching and decoding of an undefined code are detected, the simulation process is stopped and a notification is provided to the user. As a result, the user can immediately recognize the detection of an undefined code, and can easily understand that loading of firmware is highly likely to be unsuccessful, and can immediately address that trouble appropriately.

### 2. Second Embodiment

### [2-1. Configuration of Image Formation Apparatus]

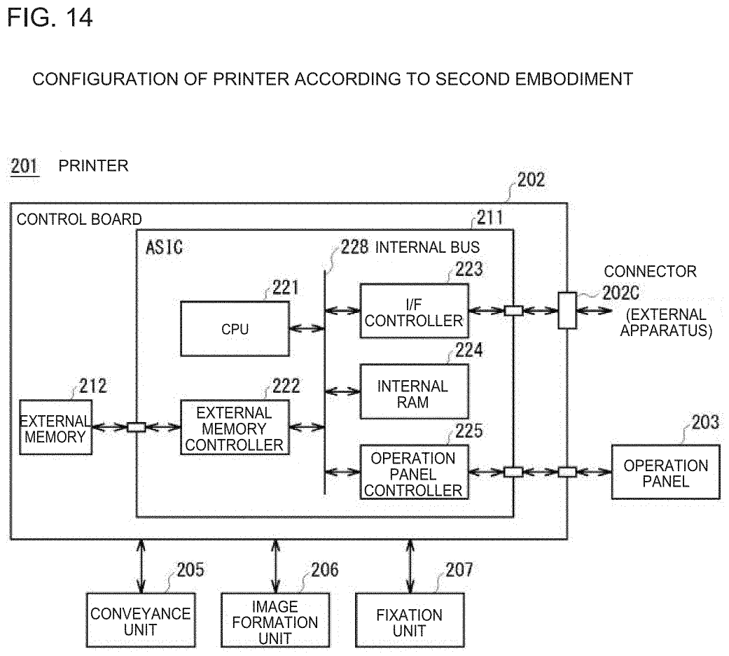

As indicated by a schematic block diagram illustrated in FIG. 14, in a printer 201 according to a second embodiment, an operation panel 203, a conveyance unit 205, an image formation unit 206, and a fixation unit 207, etc., are coupled to a control board 202. Incidentally, the actual printer 201, which is also called an “image formation apparatus,” has a configuration similar to that of the printer body section 61 displayed as an image in the model display window 60 of FIG. 3.

An ASIC 211 and an external memory 212 are provided on the control board 202. In the ASIC 211, a CPU 221, an external memory controller 222, an interface (I/F) controller 223, an internal RAM 224, and an operation panel controller 225 are coupled together through an internal bus 228.

The CPU 221, which corresponds to the CPU model 31 in a first embodiment, is not a model on software, and is an actual CPU including a combination of semiconductor elements, etc. The CPU 221 includes a computation unit, various registers, and a program counter, etc. (none of them is illustrated).

The external memory controller 222 is coupled to the external memory 212. The external memory 212, which is, for example, a flash memory and in which predetermined addresses are assigned, can store various programs and data, etc. The external memory controller 222 can access the external memory 212 to read and write various programs and data, etc., from and to the external memory 212.

The interface controller 223, which is, for example, a physical interface for a wired LAN compliant with the standard IEEE802.3ab/u or the like, is coupled to a higher-level apparatus or an external apparatus, such as a computer (not illustrated), through a connector 202C provided on the control board 202. Therefore, the interface controller 223 can, for example, receive and supply a command and data from an external apparatus to the CPU 221. The internal RAM 224 can store various programs and data, etc.

The operation panel controller 225 is coupled to the operation panel 203. The operation panel 203 includes, for example, a touch panel which is a liquid crystal panel with a built-in touch sensor, a display lamp including an LED, etc., and various operation buttons, etc. The operation panel 203 can display various kinds of information on the touch panel based on the control of the operation panel controller 225, and receive the user's touch operation or operation of pressing down an operation button, etc.

In addition, for the CPU 221, 2-byte command codes are previously defined like the CPU model 31 in a first embodiment. The CPU 221 regards data read and obtained from the external memory 212 or the like as a command code, and executes a process corresponding to that command code. In addition, for the CPU 221, like a first embodiment, only a portion of 256 values of 2-byte data are previously defined as a command code, and the remainder of the 256 values is undefined. The CPU 221, when obtaining an undefined command code (i.e., an undefined code), performs an exceptional process such as jumping to a predetermined address like a first embodiment.

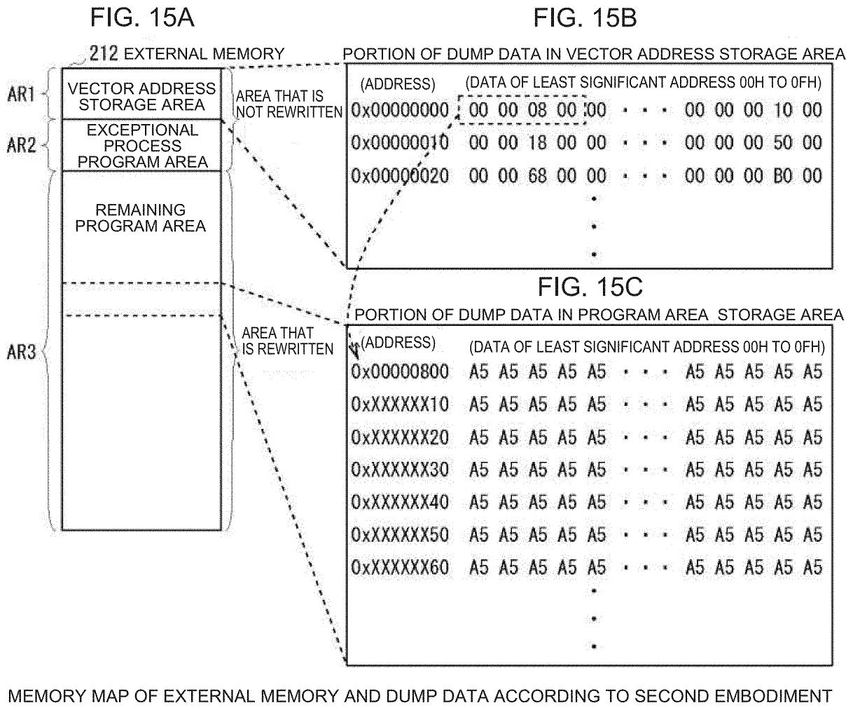

Incidentally, as indicated by a schematic memory map illustrated in FIG. 15A, the external memory 212 is roughly provided with a vector address storage area AR1, an exceptional process program area AR2, and a remaining program area AR3, which are sequentially arranged with the vector address storage area AR1 closest to or including the beginning address of the external memory 212.

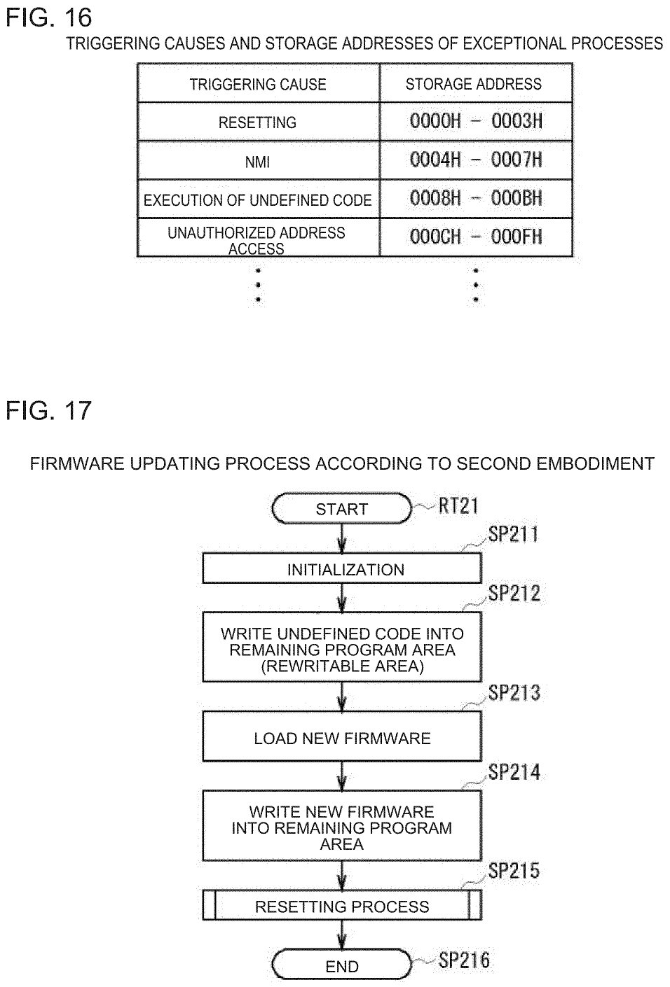

The vector address storage area AR1 is a table storing the beginning address (i.e., a vector address) of a program (hereinafter referred to as an “exceptional process program”) corresponding to each exceptional process. In the printer 201, as illustrated in, for example, FIG. 16, the cause for each exceptional process is previously associated with a storage address at which the beginning address of the corresponding exceptional process program is stored.

The exceptional process program area AR2 (FIG. 15A) stores exceptional process programs that are triggered by causes other than resetting. The remaining program area AR3 stores various programs such as firmware (i.e., a control program). A vector address for the case where the triggering cause is resetting stores an address in the remaining program area AR3. For the sake of convenience, the exceptional process program area AR2 is also hereinafter referred to as an “exceptional process program storage area, and the remaining program area AR3 is also hereinafter referred to as a “control program storage area.”

Such a configuration allows the CPU 221 to, when an exceptional process excluding resetting has occurred, read the beginning address of an exceptional process program from a storage address in the vector address storage area AR1 corresponding to the triggering cause of the exceptional process, and sets the read beginning address into the program counter. As a result, the CPU 221 jumps to that beginning address (i.e., in the exceptional process program area AR2), and executes the exceptional process program.

When resetting has occurred, the CPU 221 also reads the beginning address of an exceptional process program from a storage address in the vector address storage area AR1 corresponding to resetting, and sets the read beginning address into the program counter. As a result, the CPU 221 jumps to that address (i.e., in the remaining program area AR3), and sequentially reads and executes command codes.

Furthermore, in the printer 201, when firmware is updated, the vector address storage area AR1 and the exceptional process program area AR2 of the external memory 212 are left unchanged, and only the remaining program area AR3 is updated. Therefore, in the printer 201, even when the process of updating firmware is not successful, and therefore, firmware is not stored in the remaining program area AR3, reading of each vector address and execution of each exceptional process program can be performed in the vector address storage area AR1 and the exceptional process program area AR2.

### [2-2. Firmware Updating Process]

Next, a process of updating firmware (control program) in the printer 201 is described. The CPU 221 (FIG. 14) of the printer 201 reads a predetermined updating program from the external memory 212 through the external memory controller 222, and executes the predetermined updating program to start a firmware updating process RT21 illustrated in FIG. 17, and proceeds to the first step SP211.

In step SP211, the CPU 221 performs an initialization process, and proceeds to the next step SP212. At this time, the CPU 221 performs, as the initialization process, for example, a process of setting a beginning address from which new firmware is to be written, to the beginning address of the remaining program area AR3.

In step SP212, the CPU 221 writes an undefined code, e.g., “A5H,” into the entire remaining program area AR3, and proceeds to the next step SP213. As a result, in the remaining program area AR3, the undefined code “A5H” is written at each address, as indicated by dump data illustrated in FIG. 15C, for example.

In step SP213, the CPU 221 loads (i.e., receives) new firmware from n external apparatus (not illustrated) through the interface controller 223 and the connector 202C, and proceeds to the next step SP214.

In step SP214, the CPU 221 writes the loaded new firmware into the remaining program area AR3 from the beginning address set in step SP211, and proceeds to the next step SP215. At this time, the CPU 221 writes command codes of the new firmware by overwriting the undefined code “A5H” written at each address in step SP212.

Therefore, in the printer 201, for example, when power supply is shut off during the process of writing new firmware into the external memory 212, or when obtaining of new firmware from an external apparatus is interrupted partway, the undefined code “A5H” is left in the remaining program area AR3 of the external memory 212.

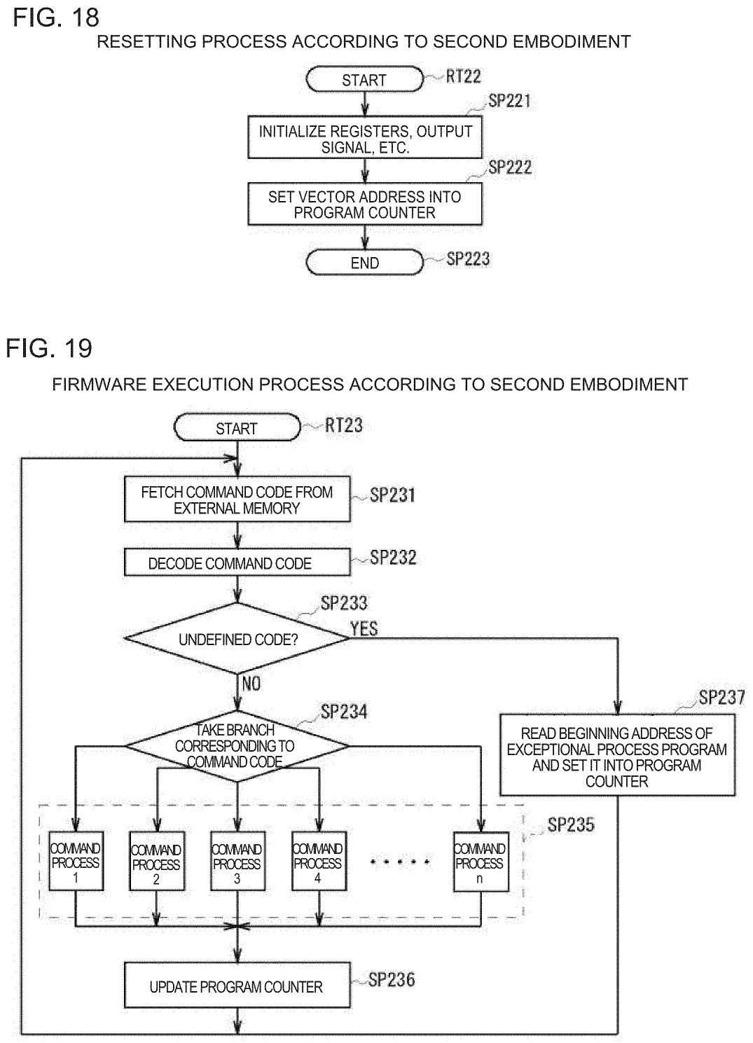

In step SP215, the CPU 221 executes a resetting process as a subroutine. Specifically, the CPU 221 starts a resetting process RT22 of FIG. 18, and proceeds to step SP221. In step SP221, the CPU 221 initializes each register (not illustrated), an output signal, etc., and proceeds to the next step SP222.

In step SP222, the CPU 221 reads the start address “00000800H,” as an address from which a program is started, from the address “0000H” (FIG. 16) at which a start address for a resetting interruption process is stored, and sets the start address into the program counter. Thereafter, the CPU 221 proceeds to the next step SP223, and ends the resetting process RT22.

Thereafter, the CPU 221 sequentially reads command codes from “00000800H,” which is the start address set in the program counter after resetting, and starts executing firmware. Incidentally, even when power supply is shut off during updating of firmware, and thereafter, power supply is turned on again, the CPU 221 performs the resetting process.

Specifically, the CPU 221 starts a firmware execution process RT23 illustrated in FIG. 19, and proceeds to step SP231. In step SP231, the CPU 221 fetches (i.e., obtains) a command code from an address in the external memory 212 indicated by the program counter, and proceeds to the next step SP232.

In steps SP232 to SP236, the CPU 221 executes processes similar to steps SP21 to SP26, respectively, of the firmware execution process RT3 (FIG. 9) in a first embodiment.

Of these steps, when the result in step SP233 is negative, this means that the command code decoded in step SP232 is not an undefined code, and is one of the previously defined command codes. This also means that at the current address in the external memory 212, firmware has been normally written in step SP214 after an undefined code was written in step SP212 (FIG. 17). At this time, the CPU 221 executes a process corresponding to the command code in steps SP234 to SP235.

Meanwhile, when the result of the determination in step SP233 is positive, this means that the command code is an undefined code, and therefore, at the current address in the external memory 212, firmware has not been normally written in step SP214 after an undefined code was written in step SP212 (FIG. 17). This also means that at least a portion of firmware has not been normally written in the external memory 212, and therefore, the printer 201 cannot be operated normally. At this time, the CPU 221 proceeds to the next step SP237.

In step SP237, the CPU 221 reads the beginning address of an exceptional process program from the storage address (e.g., “0008H-000BH”) of “execution of an undefined code” in the vector address storage area AR1, which corresponds to a triggering cause for an exceptional process, and sets that beginning address into the program counter.

Incidentally, the exceptional process program of “execution of an undefined code,” which is stored in the exceptional process program area AR2 (FIG. 15A) as described above, is not rewritten when firmware is updated. Therefore, even when the firmware has failed to be written, the exceptional process program of “execution of an undefined code” is left in the external memory 212.

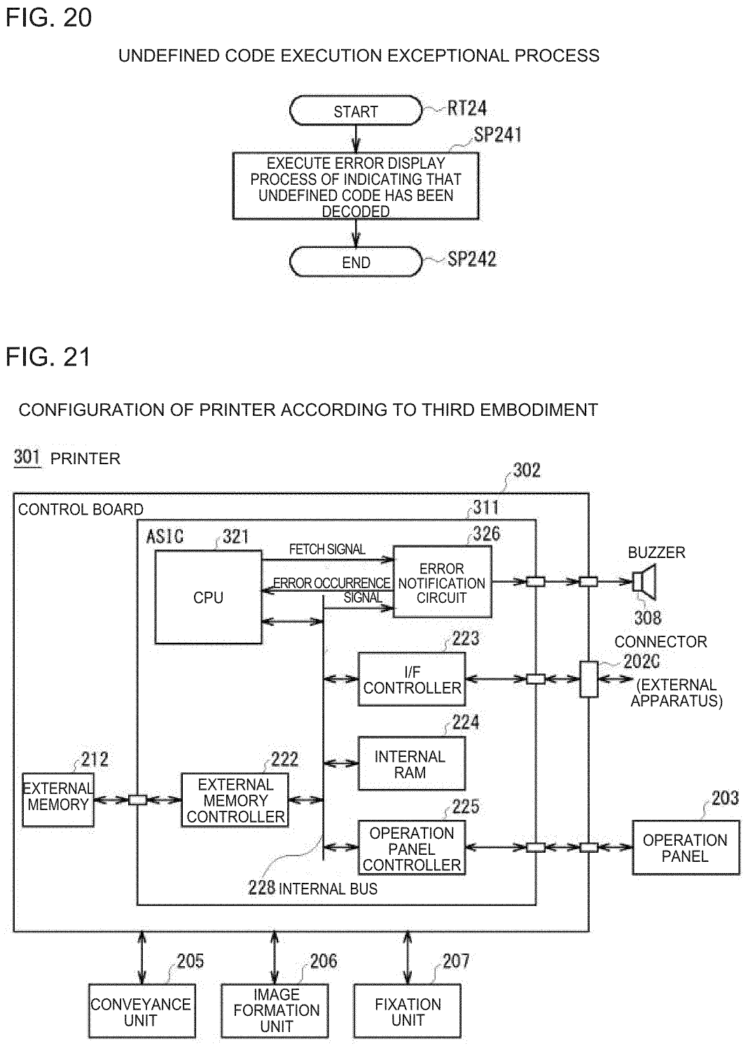

As a result, the CPU 221 starts an undefined code execution exceptional process RT24 illustrated in FIG. 20 as a subroutine, and proceeds to step SP241. In step SP241, the CPU 221 controls the operation panel controller 225 (FIG. 14) so that a predetermined error display screen is displayed on the touch panel of the operation panel 203.

Like the abnormality notification window 80 (FIG. 10) in a first embodiment, the error display screen displays text, graphics, etc., indicating that an error has occurred, that an undefined code has been decoded, etc. Thereafter, the CPU 221 proceeds to the next step SP242, and ends the undefined code execution exceptional process RT24.

### [2-3. Effects, Etc.]

In the above configuration, in the printer 201 according to a second embodiment, the vector address storage area AR1, the exceptional process program area AR2, and the remaining program area AR3 are provided in the external memory 212 (FIG. 15A), and only the remaining program area AR3 is rewritten when firmware is updated.

In this case, in the printer 201, when firmware is updated, an undefined code is written in the entire remaining program area AR3, and new firmware is then written into the remaining program area AR3, and thereafter, the resetting process is performed.

Therefore, in the printer 201, when new firmware has failed to be written, an undefined code is left at at least a portion of the addresses in the remaining program area AR3 of the external memory 212.

For example, as illustrated in FIGS. 15A to 15C, in the firmware updating process RT21 (FIG. 17), at the address “00000800H,” command codes of new firmware are not written in step SP214 after the undefined code “A5H” has been written in step SP212, and therefore, the undefined code “A5H” remains unchanged.

In this case, in the CPU 221 of the printer 201, in the firmware execution process RT23 (FIG. 19), initially, the storage address of an exceptional process whose triggering cause is resetting in the vector address storage area AR1 is “0000H-0003H” (FIG. 16), and therefore, the address “00000800H” is set into the program counter (FIGS. 15A to 15C).

Next, the CPU 221 fetches and decodes the undefined code “A5H” from the address“00000800H.” The result of step SP233 is positive. In step SP237, the undefined code execution exceptional process RT24 (FIG. 20) is executed, and a predetermined error display screen can be displayed on the touch panel of the operation panel 203.

As a result, when the process of updating firmware has failed, so that firmware is not appropriately stored in the remaining program area AR3 of the external memory 212, the printer 201 displays an error display screen on the operation panel 203 so that the user can recognize that the firmware has not been normally written.

As a result, the printer 201 allows the user to take appropriate measures, such as shutting off power supply, reupdating firmware, and arranging for a maintenance personnel, so as to restore itself to a normal condition. Therefore, it is possible to prevent or reduce damage to hardware that is caused due to continuation of the out-of-control condition of the CPU 221.

In other words, in the printer 201 according to a second embodiment, like the simulation apparatus 1 according to a first embodiment, an undefined code is previously written before firmware is written or updated, and therefore, it can be easily determined whether or not firmware has failed to be written or updated, based on whether or not the undefined code has been decoded.

In addition, in the printer 201, when firmware is updated, only the remaining program area AR3 is rewritten instead of rewriting the entire external memory 212. As a result, in the printer 201, a vector address and an exceptional process program can be maintained during the process of updating firmware, and even when the firmware has failed to be updated, the user can, for example, be notified using a remaining vector address or exceptional process program.

From another perspective, in the printer 201, even when firmware has not been written in the remaining program area AR3, an error display screen can be displayed using data stored in the vector address storage area AR1 and the exceptional process program area AR2. Therefore, in the printer 201, it is not necessary to additionally provide dedicated hardware for monitoring the CPU 221, and the ASIC 211, which has a general configuration, can be directly used, resulting in a reduction in costs of design, verification of operation, etc.

In other respects, a second embodiment may have advantageous effects similar to those according to a first embodiment.

With the above configuration, in the printer 201 according to a second embodiment, when firmware is updated, an undefined code is previously written in the entire remaining program area AR3 of the external memory 212 before the process of writing new firmware is performed. In the printer 201, when writing of firmware has not been normally completed, a firmware execution process is performed with the undefined code written in the remaining program area AR3 left. Therefore, when fetching and decoding of the undefined code have been detected, an exceptional process is executed so that an error display screen is displayed on the operation panel 203 to notify the user of such a situation. As a result, the user can immediately recognize the detection of the undefined code, and easily estimate that writing of firmware is highly likely to be unsuccessful, and therefore, can quickly take appropriate measures.

### 3. Third Embodiment

### [3-1. Configuration of Image Formation Apparatus]

As indicated by a schematic block diagram illustrated in FIG. 21 corresponding to FIG. 14, a printer 301 according to a third embodiment is similar to the printer 201 according to a second embodiment, except that the printer 301 has a control board 302 instead of the control board 202, and has a buzzer 308. The buzzer 308, which is coupled to the control board 302, makes a sound or stops buzzing based on the control of the control board 302.

The control board 302 is similar to the control board 202 according to a second embodiment (FIG. 14), except that the control board 302 has an ASIC 311 instead of the ASIC 211. The ASIC 311 is similar to the ASIC 211 according to a second embodiment, except that the ASIC 311 has a CPU 321 instead of the CPU 221, and has an the error notification circuit 326.

Note that unlike the printer 201 according to a second embodiment, in the printer 301, firmware stored in the external memory 212 is transferred (i.e., copied) to the internal RAM 224 before the CPU 321 sequentially reads command codes of the firmware from the internal RAM 224.

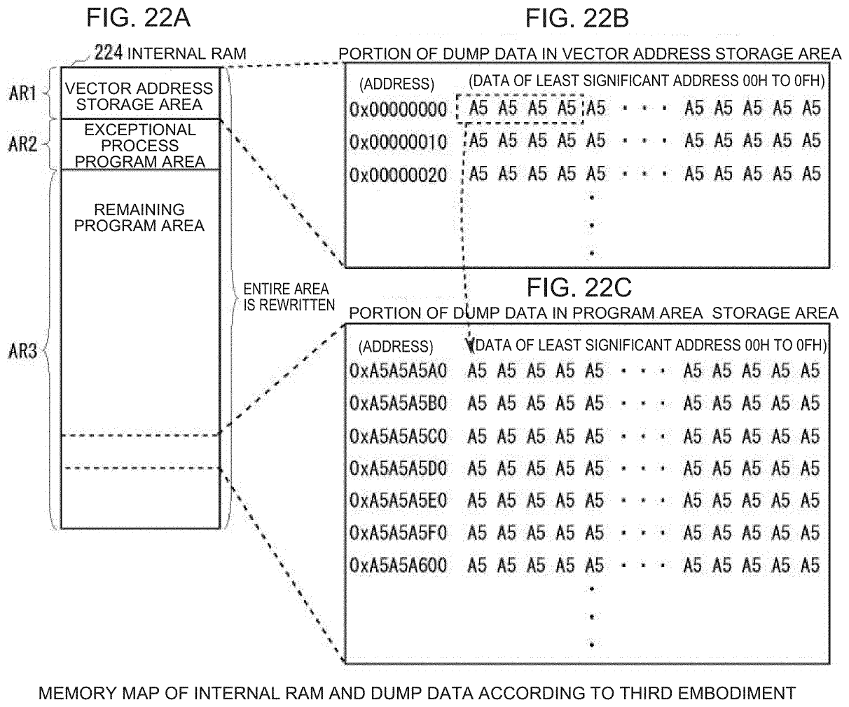

As indicated by a schematic memory map illustrated in FIG. 22A corresponding to FIG. 15A, like the external memory 212 according to a second embodiment, the internal RAM 224 includes a vector address storage area AR1, an exceptional process program area AR2, and a remaining program area AR3, which are sequentially arranged with the vector address storage area AR1 closest to or including the beginning address of the internal RAM 224.

Note that unlike when firmware is updated in a second embodiment, in the printer 301, when firmware is transferred from the external memory 212 to the internal RAM 224, the vector address storage area AR1, the exceptional process program area AR2, and the remaining program area AR3 are all entirely rewritten.

The error notification circuit 326 (FIG. 21) includes a CPU, ROM, and RAM, etc. (not illustrated). The ROM previously stores a predetermined error notification program. The error notification circuit 326 is coupled to the CPU 321 and the internal bus 228. The CPU 321, when fetching a command code, generates and sends a fetch signal to the error notification circuit 326. As a result, the error notification circuit 326 can know the command code fetch cycle of the CPU 321.

The error notification circuit 326 also monitors the internal bus 228 to obtain data flowing on the internal bus 228. Various kinds of data flow on the internal bus 228. At some timings, data (i.e., a command code) read from the internal RAM 224 by the CPU 321 is flowing.

The error notification circuit 326 also determines whether or not data (i.e., a command code) obtained from the internal bus 228 is an undefined code. When the result of the determination is positive, the error notification circuit 326 is allowed to control the buzzer 308 so that the buzzer 308 makes a sound, e.g., a predetermined notification sound.

### [3-2. Firmware Transfer Process]

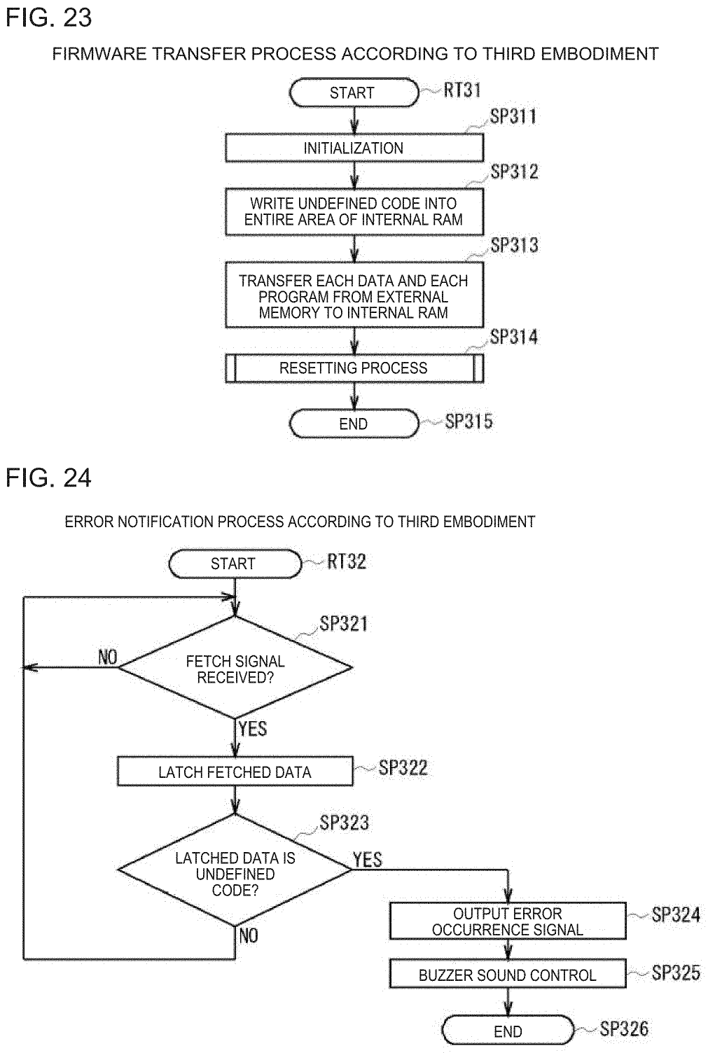

Next, a process of transferring firmware (control program) in the printer 301 is described. The CPU 321 of the printer 301 (FIG. 21) reads a predetermined transfer program from the external memory 212 through the external memory controller 222, executes the predetermined transfer program to start a firmware transfer process RT31 illustrated in FIG. 23, and proceeds to the first step SP311.

In step SP311, the CPU 321 performs an initialization process, and proceeds to the next step SP312. At this time, the CPU 321 performs, as the initialization process, for example, a process of setting the beginning address from which firmware is to be written into the internal RAM 224, to the beginning address of the vector address storage area AR1.

In step SP312, the CPU 321 writes an undefined code, e.g., “A5H,” into the entire area of the internal RAM 224, and proceeds to the next step SP313. As a result, for example, as indicated by dump data illustrated in FIGS. 22B and 22C, the undefined code “A5H” is written in the entire area of the internal RAM 224.

In step SP313, the CPU 321 sequentially transfers each data and each program, i.e., a vector address, an exceptional process program, and firmware, etc., from the external memory 212 to the internal RAM 224 through the external memory controller 222, and proceeds to the next step SP314. At this time, the CPU 321 overwrites the internal RAM 224, in which the undefined code “A5H” has been written at each address in step SP312, with each data or each command code of each program.

Therefore, in the printer 301, when transfer of each data or each program from the external memory 212 to the internal RAM 224 is interrupted partway due to occurrence of an error or the like, the undefined codes “A5H” is left in the internal RAM 224.

In step SP314, like a second embodiment, the CPU 321 executes a resetting process as a subroutine, and proceeds to the next step SP315, in which the CPU 321 ends the firmware transfer process RT31.

As a result, like a second embodiment, the CPU 321 reads, as the address from which a program is started, a start address from the address “0000H” (FIG. 16) at which the start address of an interruption process for resetting is stored, and sets the start address into the program counter. Thereafter, the CPU 321 sequentially reads command codes from the start address in the internal RAM 224 to start execution of firmware. At this time, the CPU 321 transmits a fetch signal to the error notification circuit 326 each time the CPU 321 fetches a command code from the internal RAM 224.

Meanwhile, when power supply is turned on, the error notification circuit 326 starts an error notification process RT32 illustrated in FIG. 24, and proceeds to the first step SP321. In step SP321, the error notification circuit 326 determines whether or not a fetch signal has been received from the CPU 321. Here, when the result of the determination is negative, the error notification circuit 326 waits until a fetch signal is received from the CPU 321 each time step SP321 is performed.

Meanwhile, when the result of the determination in step SP321 is positive, this means that a fetch signal has been received from the CPU 321, and therefore, the error notification circuit 326 needs to obtain the same command code as that which has been fetched by the CPU 321. At this time, the error notification circuit 326 proceeds to the next step SP322.

In step SP322, the error notification circuit 326 latches (i.e., obtains) data (i.e., a command code) from the internal bus 228, and proceeds to the next step SP323. In step SP323, the error notification circuit 326 determines whether or not the data latched from the internal bus 228 is an undefined code.

Here, when the result of the determination is negative, this means that the command code fetched by CPU 321 is not an undefined code, and therefore, concerning at least that command code, this means that in step SP313 (FIG. 23), each data or each program has been normally transferred from the external memory 212 to the internal RAM 224. At this time, the error notification circuit 326 returns to step SP321 again, in which the error notification circuit 326 waits until the next command code is fetched by the CPU 321.

Meanwhile, when the result of the determination in step SP321 is positive, this means concerning at least the address from which that command code has been fetched, an undefined code written in step SP312 (FIG. 23) is left. In other words, this means that concerning that address, each data or each program has failed to be normally transferred from the external memory 212 to the internal RAM 224 in step SP313 (FIG. 23). At this time, the error notification circuit 326 proceeds to the next step SP324.

In step SP324, the error notification circuit 326 generates and transmits an error occurrence signal to the CPU 321, and proceeds to the next step SP325. In response to this, the CPU 321 executes a predetermined exceptional process. In step SP325, the error notification circuit 326 causes the buzzer 308 to make a sound, and thereby notifies the user that an undefined code has been fetched and decoded. Thereafter, the error notification circuit 326 proceeds to the next step SP326, and ends the error notification process RT32.

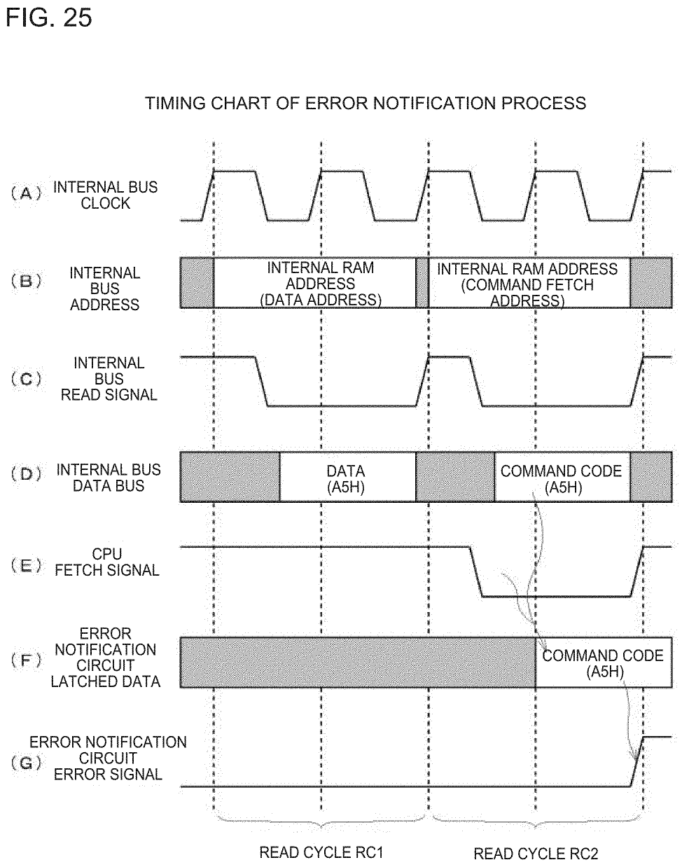

Here, timings of various kinds of data and signals in the error notification process in the printer 301 are described with reference to a timing chart illustrated in (A) to (D) in FIG. 25. (A) to (D) in FIG. 25 illustrate clocks, addresses, a read signal, and a data bus, respectively, of the internal bus 228. (E) in FIG. 25 illustrates a fetch signal for the CPU 321. (F) and (G) in FIG. 25 illustrate latched data and an error signal, respectively, of the error notification circuit 326.

The clock (A) of the internal bus 228 is a clock signal generated in a clock circuit (not illustrated) provided in the ASIC 311. Each circuit in the ASIC 311 and the internal bus 228 are operated in synchronization with the clock signal. For the sake of convenience, in FIG. 25, the two earlier clocks are hereinafter referred to as a read cycle RC1, and the two later clocks are hereinafter referred to as a read cycle RC2.

The address (B) of the internal bus 228 represents data indicating an address in the internal bus 228 and flowing on the address bus. The read signal (C) represents a timing that data is read from the internal bus 228, and has negative logic. The data bus (D) represents data itself of the internal bus 228 and flowing on the data bus.

The fetch signal (E) of the CPU 321 represents a timing that a fetch process is performed in the CPU 321, and has negative logic. The latched data (F) of the error notification circuit 326 represents data latched from the internal bus 228 by the error notification circuit 326. The error signal (G) is generated by the error notification circuit 326 when data latched by the error notification circuit 326 is an undefined code, and has positive logic.

In the earlier read cycle RC1 of FIG. 25, the CPU 321 reads a data address from the internal RAM 224. In other words, in this case, the CPU 321 does not read a command code, i.e., does not perform a fetch process. In this case, the fetch signal (E) remains at the high level indicating an inactive state. At this time, the error notification circuit 326 does not latch data from the internal bus 228, and does not perform a process of determining whether or not latched data is an undefined code.

Meanwhile, in the later read cycle RC2 of FIG. 25, the CPU 321 reads a command fetch address from the internal RAM 224. Specifically, in this case, the CPU 321 reads a command code and performs a fetch process, and therefore, causes the fetch signal (E) to go to the low level. At this time, the error notification circuit 326 latches data (i.e., a command code) from the internal bus 228 (F), and performs a process of determining whether or not the latched data includes an undefined code. Here, since the latched command code is the undefined code “A5H,” the error notification circuit 326 causes the error signal (G) to go to the high level, i.e., an active state, and notifies the CPU 321 of the occurrence of an error.

### [3-3. Effects, Etc.]

With the above configuration, in the printer 301 according to a third embodiment, an undefined code is written into the entire area of the internal RAM 224 after the printer 301 is activated, and thereafter, each data and each program are transferred and written from the external memory 212 into the internal RAM 224. Thereafter, the printer 301 performs the resetting process, and the CPU 321 accesses the internal RAM 224 to read a command code, and executes the command code.

In the printer 301, the error notification circuit 326 provided in the ASIC 311 latches a command code from the internal bus 228 based on a fetch signal obtained from the CPU 321, and determines whether or not the latched command code is an undefined code.

In the printer 301, when each data and each program have failed to be transferred from the external memory 212 to the internal RAM 224, an undefined code is left at at least a portion of the addresses of the internal RAM 224. In such a case, at the stage that the CPU 321 has fetched that undefined code, the printer 301 determines that the command code which the error notification circuit 326 has latched from the internal bus 228 is the undefined code, transmits an error occurrence signal to the CPU 321, and causes the buzzer 308 to make a sound.

As a result, in the printer 301, even when each data or each program has not been normally written into the internal RAM 224, and therefore, the CPU 321 cannot perform a normal error process, the error notification circuit 326 can cause the buzzer 308 to make a sound, and thereby, notify the user that an error has occurred in the printer 301.

In other words, like the simulation apparatus 1 according to a first embodiment, etc., in the printer 301 according to a third embodiment, an undefined code is previously written before firmware or the like is written, and therefore, it can be easily determined whether or not the firmware has failed to be written, based on whether or not the undefined code has been fetched.

In the printer 301, unlike the printer 201 according to a second embodiment, the error notification circuit 326, which is provided separately from the CPU 321, determines whether or not a command code fetched by the CPU 321 is an undefined code. Therefore, in the printer 301, the load of processing can be reduced compared to when the above determination is performed by the CPU 321. In addition, in the printer 301, for example, each data stored in the vector address storage area AR1 and the exceptional process program area AR2 of the external memory 212 can be previously replaced to update a vector address and an exceptional process program in the internal RAM 224.

In other respects, a third embodiment can have advantageous effects similar to those of a first and a second embodiment.

With the above configuration, in the printer 301 according to a third embodiment, an undefined code is written into the entire area of the internal RAM 224 after the printer 301 is activated, and thereafter, each data and each program are transferred and written from the external memory 212 into the internal RAM 224. When each data or each program has not been normally transferred, the printer 301 executes firmware with a written undefined code left, and therefore, when the undefined code is fetched, the error notification circuit 326 detects such fetch and causes the buzzer 308 to make a sound and thereby notify the user of such a situation. As a result, the user can immediately recognize that an abnormality has occurred in the printer 301, and take appropriate measures.

### 4. Modifications

Note that in a first embodiment, in step SP2 of the simulation process RT1 (FIG. 4), “A5H” is written as an undefined code into the ROM model 32. However, the invention is not limited to this, and various other undefined codes may be written. Briefly, a code to which a command is not assigned in the CPU model 31 may be used as an undefined code. This is also true of a second and a third embodiment.

In a first embodiment, the undefined code “A5H” is written into the entire area of the ROM model 32. However, the invention is not limited to this. For example, an undefined code may be written into a portion of the ROM model 32, e.g., near a start address, or near an address indicated when an undefined code is a vector address. As a result, the time it takes to write an undefined code can be reduced. This is also true of a second and a third embodiment.

Furthermore, in a first embodiment, the abnormality notification window 80 (FIG. 10) displays a message indicating that an undefined code has been decoded and a message that a simulation process has been stopped. However, the invention is not limited to this. For example, the user may be notified of other kinds of information, e.g., the abnormality notification window 80 may display a message that loading of firmware is likely to be unsuccessful. This is also true of a second embodiment.

Furthermore, in a third embodiment, the printer 301 is provided with the buzzer 308. When the error notification circuit 326 determines that data fetched in the CPU 321 is an undefined code, the buzzer 308 is caused to make a sound. However, the invention is not limited to this. For example, the printer 301 may be provided with a notification lamp such as an LED, and the notification lamp may be turned on or may be caused to flicker. In addition, like a second embodiment, the operation panel 203 may display a predetermined error display screen. Furthermore, the above features may be combined as appropriate.

Furthermore, in a third embodiment, the error notification circuit 326 is provided in the ASIC 311 (FIG. 21). However, the invention is not limited to this. For example, the error notification circuit 326 may be configured as a semiconductor chip that is independent of the ASIC 311 on the control board 302. In that case, a fetch signal of the CPU 321 and data flowing on the internal bus 228 may be supplied from the ASIC 311 to the error notification circuit 326.

In addition, in a first embodiment, the simulation apparatus 1 performs a process of simulating a printer. However, the invention is not limited to this. For example, the simulation apparatus 1 may perform a process of simulating various other information apparatuses.

Furthermore, in a second embodiment, firmware for the printer 201 is updated. However, the invention is not limited to this. For example, the invention may be applied to the case where firmware is updated in various other information apparatuses. This is also true of a third embodiment.

Furthermore, in a first embodiment, the simulation apparatus 1 reads firmware from the storage unit 3. However, the invention is not limited to this. For example, firmware may be obtained (received) from an information processing apparatus such as a server apparatus (not illustrated) coupled to the simulation apparatus 1 through the communication unit 4 and a predetermined network.

Furthermore, in a first embodiment, a simulation program executed by the simulation apparatus 1 is stored in the storage unit 3. However, the invention is not limited to this. For example, a simulation program may be obtained from an information processing apparatus such as a server apparatus (not illustrated) coupled to the simulation apparatus 1 through the communication unit 4 and a predetermined network.

The invention is not limited to one or more embodiments and modifications described above. That is, the invention is applicable to an embodiment including any suitable combination of some or all of one or more embodiments and modifications described above, and an embodiment including a portion of one or more embodiments and modifications described above.

In one or more embodiments described above, the simulation apparatus 1 includes the model production unit 11 as a model production unit, the undefined code writing unit 13 as an undefined code writing unit, the control program writing unit 14 as a control program writing unit, the command code execution unit 15 as a command code execution unit. However, the invention is not limited to this. A simulation apparatus may include a model production unit, undefined code writing unit, control program writing unit, and command code execution unit that have various other configurations.

The invention may be applicable to a simulation apparatus that performs a process of simulating an information processing apparatus, e.g., a printer.

The invention includes other embodiments or modifications in addition to one or more embodiments and modifications described above without departing from the spirit of the invention. One or more embodiments and modifications described above are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

1. A simulation apparatus comprising:
a CPU model that mimics a central processing unit (CPU) which reads and executes command codes;
a model production unit that produces a storage unit model which mimics a storage unit which stores a control program including the command codes;
an undefined code writing unit that writes an undefined code which is not defined in the CPU, into at least a portion of a storage area of the storage unit model;
a control program writing unit that writes the control program specified by a user, into the storage area of the storage unit model in which the undefined code has been written; and
a command code execution unit that sequentially reads the command codes from the storage unit model and causes the CPU model to sequentially execute the command codes.

2. The simulation apparatus according to claim 1, further comprising:
an abnormality processing unit that notifies the user that the undefined code has been read when the command code read from the storage unit model is the undefined code.

3. The simulation apparatus according to claim 2, wherein
when the command code read from the storage unit model is the undefined code, the abnormality processing unit causes the command code execution unit to stop reading and executing the command code.

4. The simulation apparatus according to claim 1, wherein
the undefined code writing unit writes the undefined code into the storage area of the storage unit model that includes an address which is first read by the CPU.

5. The simulation apparatus according to claim 1, wherein
the undefined code writing unit writes the undefined code into the storage area of the storage unit model that includes an address to which the CPU first jumps.

6. The simulation apparatus according to claim 1, wherein
the undefined code writing unit writes the undefined code into the entire storage area of the storage unit model.

7. A simulation method comprising:
forming a CPU model that mimics a CPU which reads and executes command codes, and a storage unit model which mimics a storage unit which stores a control program including the command codes, using a model production unit;
writing an undefined code which is not defined in the CPU, into at least a portion of a storage area of the storage unit model, using an undefined code writing unit;
writing the control program specified by a user, into the storage area of the storage unit model in which the undefined code has been written, using a control program writing unit; and
sequentially reading the command codes from the storage unit model and causing the CPU model to sequentially execute the command codes, using a command code execution unit.

8. An information processing apparatus comprising:
a CPU that reads and executes command codes;
a storage unit that stores a control program including the command codes;
an undefined code writing unit that writes an undefined code which is not defined in the CPU, into at least a portion of a storage area of the storage unit;
a control program writing unit that writes the control program into a storage area of a storage unit model in which the undefined code has been written; and
an abnormality processing unit that when the CPU reads and executes the command code of the control program from the storage unit wherein the command code is the undefined code, performs at least one of a stopping process of stopping an execution of the control program and a notification process of notifying that the undefined code has been read.

9. The information processing apparatus according to claim 8, wherein
the storage unit has a control program storage area that stores the control program, and in addition, an exceptional process program storage area that stores an exceptional process program which executes an exceptional process,
the undefined code writing unit writes the undefined code into the control program storage area of the storage unit without writing the undefined code into the exceptional process program storage area, and
the control program writing unit writes the control program into the control program storage area of the storage unit.

10. The information processing apparatus according to claim 8, wherein
the abnormality processing unit is an error notification circuit configured separately from the CPU.

11. The information processing apparatus according to claim 10, wherein
the abnormality processing unit latches the command code supplied from the storage unit to the CPU, and determines whether or not the command code is the undefined code.
